(19) United States
(12) Patent Application Publication
(10) Pub. No.: US 2007/0069335 A1
(43) Pub. Date: Mar. 29, 2007

(54) Bonded wafer and its manufacturing method

(76) Inventors: Akihiko Endo, Tokyo (JP); Hideki Nishihata, Tokyo (JP)

Correspondence Address: GREENBLUM & BERNSTEIN, P.L.C., 1950 ROLAND CLARKE PLACE, RESTON, VA, 20191, US

(21) Appl. No.: 10/570,665

(22) PCT Filed: Sep. 8, 2004
(86) PCT No.: PCT/JP04/13067

§ 371 Date: Mar. 6, 2006

(30) Foreign Application Priority Data
Sep. 8, 2003 (JP) 2003-315986

(51) Int. Cl. H01L 29/06; H01L 21/46

(52) U.S. Cl. 257/618; 438/455

(57) ABSTRACT

The bonding surfaces of an active layer wafer and a supporting wafer have fitting surfaces each comprising a part of a spherical surface of the same curvature, and they are to be bonded together with their bonding surfaces superposed with each other. As a result, an area left as not-bonded in the outer peripheral portion of the bonded wafer is reduced and thus a fixed quality area can be expanded. Therefore, the yield of the bonded SOI wafer becomes high, and the chipping, wafer peel-off and the like phenomenon in the subsequent steps of wafer processing can be reduced.

### FIELD OF THE INVENTION

The present invention relates to a bonded wafer and a manufacturing method of the same, and more particularly to a bonded wafer and a manufacturing method of the same, in which an area that has been left as not-bonded in an outer peripheral portion of the wafer is reduced so that a FQA (Fixed Quality Area) can be expanded.

### DESCRIPTION OF THE PRIOR ART

Recently, film thickness reduction of an active layer (0.05 μm or thinner) has been progressed in conjunction with a highly densified integration of devices. There has been developed the smart cut method as disclosed in the Patent Document 1 as a method for manufacturing a semiconductor substrate having an SOI (Silicon On Insulator) structure for achieving the above-mentioned film thickness reduction.

In the smart cut method, firstly a wafer for active layer, which has been processed to have an oxide film formed thereon and then ion-implanted with hydrogen at a predetermined depth thereof via the oxide film, is bonded with a supporting wafer in a room temperature. Subsequently, thus obtained bonded wafer is introduced into a furnace for heat treatment, where it is heat treated at 500° C. for 30 minutes to thereby cleave and separate a part of the active layer wafer at the site of the ion-implanted area. In this stage of processing, a specific area in an outer peripheral portion of the active layer wafer, which has been left as not-bonded due to a wafer geometry, is not cleaved or separated but the area will remain as it is in a main body portion of the active layer wafer. Following the above step, a heat treatment for bonding to enhance a bonding strength is applied to the bonded wafer. The heat treatment for bonding provides a heat treatment at 1100° C. in an atmosphere of oxygen for two hours. Thus, an SOI wafer can be produced which comprises the supporting wafer and the active layer wafer with a buried silicon oxide film interposed therebetween.

[Patent Document 1]
Japanese Patent Laid-open Publication No. Hei 5-211128

### SUMMARY OF THE INVENTION

Problem to Be Solved by the Invention

It is to be noticed that both of the active layer wafer and the supporting wafer have been mirror finished in their bonding surfaces by the MP (Mirror Polishing). The mirror finishing tends to induce abrasive drop in the outer peripheral portion of the wafer. As a result thereof, owing to this abrasive drop, the area left as not-bonded (EE (Edge Exclusion)) 111 is expanded in the outer peripheral portion of the bonded wafer 300 comprising the active layer wafer 100 and the supporting wafer 200 with the buried silicon oxide film 400 interposed therebetween and also a number of voids are generated in the bonding interface of the bonded wafer, as shown in FIGS. 6 and 7. As a result, the fixed quality area 113 of the bonded SOI wafer and thus the yield of device obtainable from the bonded SOI wafer have been reduced.

Further, the portion corresponding to the area 111 in the outer peripheral portion of the wafer, which is left as not-bonded, has a deteriorated mechanical strength as compared to the other portion (i. e., the portion corresponding to the fixed quality area 113). Consequently, as the area left as not-bonded expands more broadly, chipping, wafer peel-off and the like phenomenon are more likely to occur in the subsequent steps of wafer processing.

The present invention has been made in the light of the problems described above, and an object thereof is to provide a bonded wafer and a manufacturing method thereof, in which the area left as not-bonded can be reduced and thus the fixed quality area can be enlarged in the outer peripheral portion of the wafer.

Means to Solve the Problem

A first invention provides a manufacturing method of a bonded wafer, in which the bonded wafer is manufactured by bonding a wafer for active layer with a supporting wafer, wherein the active layer wafer and the supporting wafer, which are to be bonded together, have fitting surfaces, respectively, for fitting to each other, each of said fitting surfaces comprising a part of a spherical surface having the same curvature.

According to the first invention, the active layer wafer and the supporting wafer prepared for bonding together are to be bonded as their bonding surfaces abutting to each other. In this stage of processing, the bonding surfaces of those two wafers have the fitting surfaces, respectively, allowing for the fitting to each other. Owing to those arrangement, those two bonding surfaces can be superposed together even in the outer peripheral portion of the bonded wafer. This results in a reduced area left as not-bonded in the outer peripheral portion of the wafer. Consequently, it helps increase a fixed quality area allowable for the formation of devices within the bonded wafer. This can increase a yield of the bonded wafer and also can reduce chipping, wafer peel-off and the like phenomenon in the subsequent steps of wafer processing.

Specifically, as to the active layer wafer and the supporting wafer such types of wafer may be employed as a monocrystal silicon wafer, a germanium wafer and a silicon carbide wafer, for example.

The manufacturing method of the bonded wafer includes such a method for bonding in which after an insulating film is formed on an active layer wafer and the active layer wafer and a supporting wafer are bonded via the insulating film disposed therebetween, the bonded wafer is subjected to the steps of grinding and polishing so as to produce the SOI wafer including an SOI layer formed therein. This bonding method includes the smart cut method, in which the hydrogen gas or the noble gas element is ion-implanted into the active layer wafer via the insulating film to form the ion-implanted layer in the active layer wafer, subsequently the active layer wafer is bonded with the supporting wafer via the insulating film disposed therebetween to form the bonded wafer, and then thus obtained bonded wafer is subjected to the heat treatment so as to cleave and separate a part of the active layer wafer at the site of the ion-implanted layer as the interface.

The expression that the bonding surfaces of the two wafers provide the fitting surfaces means that a convex and a concave portions existing in the bonding surfaces have the same curvature but disposed oppositely so as to form complementary surfaces with each other. The curvature for the active layer wafer and the supporting wafer is not limited.

A second invention provides a manufacturing method of a bonded wafer as defined in the first invention, in which at least either one of the fitting surface of the active layer wafer and the fitting surface of the supporting wafer includes a hetero structure along a thickness-wise direction.

The hetero structure refers to a structure containing different types of substance in contact with each other at the site of a certain interface. The area proximal to the interface between the different types of substance defines a hetero junction of two phases having a lattice structure, a chemical composition and a thermal expansion coefficient that are different from each other. Accordingly, a stress acts on the hetero junction, and so a strain will be induced therein. Owing to this strain, a warp (deformation) is generated in the wafer having the hetero structure.

Further, those different types of substance include a combination of the same substances exclusively having different dopant concentrations, a monocrystal silicon and a polycrystal silicon, a bulk substance and an oxide film of the wafer, or a wafer bulk substance and a nitride film, for example.

It is to be noted that the wafer subject to the arrangement of the hetero structure may be the active layer wafer or the supporting wafer. Alternatively, both of the active layer wafer and the supporting wafer may be provided with the hetero structure.

According to the second invention, on the subject wafer to be provided with the hetero structure thereon (the active layer wafer and/or the supporting wafer), an epitaxial layer having a different dopant concentration (including a case of no dopant contained) from that of the subject wafer is grown epitaxially so as to create the hetero structure. Since the two wafers have different dopant concentrations from each other, the lattice constant for the substances constructing the two wafers is also different from each other. Owing to this, the strain will be generated in the vicinity of the bonding interface that will turn to be the hetero junction, and the warp will occur in the subject wafer. In this regard, thus emerged warp is used in a positive manner to thereby reduce the area that will otherwise be left as not-bonded and enlarge the fixed quality area usable for the formation of the devices.

A third invention provides a manufacturing method of a bonded wafer as defined in the second invention, in which the hetero structure is provided along the thickness-wise direction in the epitaxial growth method.

The epitaxial growth method includes the vapor phase epitaxial growth method, the liquid phase epitaxial growth method and the solid phase epitaxial growth method. The vapor epitaxial growth method includes a chemical method (CVD method: Chemical Vapor Deposition) and a physical method (PVD method: Physical Vapor Deposition).

Accordingly, the hetero structure may be constructed by growing the monocrystal silicon epitaxially and/or by depositing the film of polycrystal silicon in the CVD method, for example. If the above-discussed film is deposited over the top and back surfaces of either one of the active layer wafer and the supporting wafer, the wafer will be curved (to warp) due to the thermal expansion constant or the chemical reaction.

According to the third invention, for example, the epitaxial layer having the dopant concentration different from that of the active layer wafer or the supporting wafer is grown on the top and back surfaces of either one of those wafers (the epitaxial layer containing no dopant included in this case). Owing to this, a stress acts on the site of junction between the epitaxial layer and the wafer, and thus the strain is generated therein. This strain leads to the warp (deformation) of the wafer that has been provided with the epitaxial layer (hetero structure) thereon. Then, taking advantage of the warp positively can reduce the area otherwise to be left as not-bonded in the outer peripheral portion of the wafer and thus can enlarge the fixed quality area where the devices can be formed.

A fourth invention provides a manufacturing method of a bonded wafer as defined in the first invention, in which at least either one of the fitting surface of the active layer wafer and the fitting surface of the supporting wafer includes an insulating film along a thickness-wise direction.

The insulating film may employ an oxide film, a nitride film and the like, for example.

The thickness of the insulating film may be no thicker than 0.2 μm, for example, preferably in a range of 0.1 μm to 0.2 μm.

The thickness of the active layer is not limited. For example, the active layer of thick film may be in a range of 1 μm to 10 μm thick. Further, the active layer of thin film may be in a range of 0.01 μm to 1 μm thick.

According to the fourth invention, forming the insulating film over the subject wafer (the active layer wafer or the supporting wafer) can produce the hetero structure in the subject wafer. For example, the oxide film of one type of insulating film having a predetermined thickness may be formed on the top surface of the subject wafer, while the oxide film thicker than the oxide film in the top surface side may be formed in the back surface side of the subject wafer. In this case, the oxide film in the top surface and the oxide film in the back surface have the thermal expansion constants different from each other. Consequently, the warp may occur in the subject wafer.

Alternatively, the oxide film of one type of insulating film may be formed on the top surface of the subject wafer, while the nitride film of other type of insulating film may be formed on the back surface of the subject wafer, so as to induce the warp in the subject wafer.

A fifth invention provides a manufacturing method of a bonded wafer as defined in anyone of the first to fourth invention, in which the hetero structure or the insulating film is disposed in a top and a back surfaces, respectively, of the active layer wafer or the supporting wafer, and the hetero structure or the oxide film in the top and the back surfaces are different in thickness from each other.

According to the fifth invention, it is possible to induce the warp in the subject wafer even in the method employing the different film thickness between the top surface and the back surface of the subject wafer. Differentiating the film thickness may be achieved easily by using an HF solution. Consequently, the bonded wafer having the effect from the present invention can be manufactured inexpensively.

A sixth invention provides a manufacture method of a bonded wafer as defined in anyone of the first to fifth inventions, comprising the steps of: ion-implanting of hydrogen gas or noble gas into the active layer wafer to form an ion-implanted layer in the active layer wafer; subsequently bonding the active layer wafer with the supporting wafer to form the bonded wafer; and then heat treating the bonded wafer by holding it at a predetermined temperature so as to induce a cleavage and separation at the site of ion-implanted layer as an interface.

The element to be ion-implantedmaybe a type of noble gas, including, for example, helium (He), neon (Ne), argon (Ar), krypton (Kr), xenon (Xe) and radon (Rn), in addition to the hydrogen (H). Those elements may be provided in a single element or a chemical compound.

The dose of thelight element for the ion-implantation is not limited. For example, the dose may be in a range of 2×10¹⁶ atoms/cm² to 8×10¹⁶ atoms/cm².

The acceleration voltage of the light element during the ion-implantation may be not higher than 50 keV, preferably not higher than 30 keV and more preferably not higher than 20 keV. In the ion-implantation, using the lower acceleration voltage allows the ion to be controlled more precisely such that the ion can be concentrated in a depth of target.

The heating temperature of the bonded wafer during the cleavage process may be 400° C. or higher, preferably in a range of 400° C. to 700° C. and more preferably in a range of 450° C. to 550° C. It is difficult with the temperature lower than 400° C. to form the bubbles of light element from the ion-implanted light element. Inversely, with the temperature higher than 700° C., the oxide deposit will be formed within the active layer and it may deteriorate the properties of devices.

The heat treatment for bonding to further enhance the bonding strength between the active layer wafer and the supporting wafer may be performed after the cleavage process. The condition of thermal treatment in this step may be defined by the heat treatment at 1100° C. for two hours, for example. The atmospheric gas within the furnace for the thermal oxidation may employ oxygen, for example.

The atmosphere within the furnace during the cleavage process may be the atmosphere of non-oxidizing gas (e.g., an inactive gas such as nitrogen, argon). Alternatively, the process may be carried out in a vacuum condition.

The heating time of the bonded wafer for the cleavage may be one minute or longer, preferably in a range of 10 minutes to 60 minutes. With the heating time less than one minute, it is difficult to form the bubbles of light element which has been ion-implanted into the bonded wafer.

According to the sixth invention, the active layer wafer and the supporting wafer, each having the fitting surfaces comprising a part of the spherical surface having the same curvature, are prepared. Then, the active layer wafer is ion-implanted with the hydrogen gas or the noble gas so as to form the ion-implanted layer in the active layer wafer. Subsequently, the active layer wafer and the supporting wafer are bonded together to form the bonded wafer, and after this step, the bonded wafer is held at the predetermined temperature for the heat treatment. This makes it possible for a part of the active layer wafer to be cleaved and separated across its entire surface at the site of the ion-implanted layer as the interface. Consequently, the SOI wafer can be obtained, which has been produced in the smart cut method and in which the area otherwise to be left as not-bonded in the outer peripheral portion of the wafer has been reduced and the fixed quality area has been enlarged.

A seventh invention provides a bonded wafer manufactured by bonding an active layer wafer with a supporting wafer, in which the active layer wafer and the supporting wafer, which are to be bonded together, have fitting surfaces, respectively, for fitting to each other, each of the fitting surfaces comprising a part of a spherical surface having the same curvature.

Effect of the Invention

According to the present invention, an active layer wafer and a supporting wafer, which are to be bonded together, have fitting surfaces, respectively, and each of those fitting surfaces comprises a part of a spherical surface having the same curvature. During bonding, the active layer wafer and the supporting wafer are bonded together at the site of bonding surfaces comprising the fitting surfaces which are brought into contact with each other. In this regard, taking advantage of those fitting surfaces positively, the area otherwise to be left as not-bonded in the outer peripheral portion of the wafers can be reduced and the fixed quality area where devices may be formed can be enlarged. Consequently, the yield of the bonded wafer can be increased and any chipping, peel-off of the wafer and the like phenomenon during the subsequent steps of wafer processing can be reduced.

### BRIEF DESCRIPTION OF THE DRAWINGS

FIG. 1 is a process chart showing a manufacturing method of a bonded wafer according to a first embodiment of the present invention;

FIG. 2 is an enlarged section view of a main part showing a step of bonding in the manufacturing method of a bonded wafer according to the first embodiment of the present invention;

FIG. 3 is a plan view showing an area to be left as not-bonded in a bonded wafer according to the first embodiment of the present invention;

FIG. 4 is an enlarged section view of a main part of a bonded wafer showing a step of bonding in the manufacturing method of a bonded wafer according to another mode for carrying out the first embodiment of the present invention;

FIG. 5 is a process chart of main steps of processing showing a manufacturing method of a bonded wafer according to a second embodiment of the present invention;

FIG. 6 is an enlarged section view of a main part showing a step of bonding in a manufacturing method of a bonded wafer according to the prior art means; and

FIG. 7 is a plan view showing an area to be left as not-bonded in a bonded wafer according to the prior art means.

### DESCRIPTION OF THE REFERENCE NUMERALS

10 Active layer wafer

12a Silicon oxide film (Insulating film)

14 Hydrogen ion implanted area (Ion-implanted area)

20 Supporting wafer

30 Bonded wafer

40 Epitaxial layer

### DESCRIPTION OF THE PREFERRED EMBODIMENTS

Preferred embodiments of the present invention will now be described with reference to the attached drawings.

First Embodiment

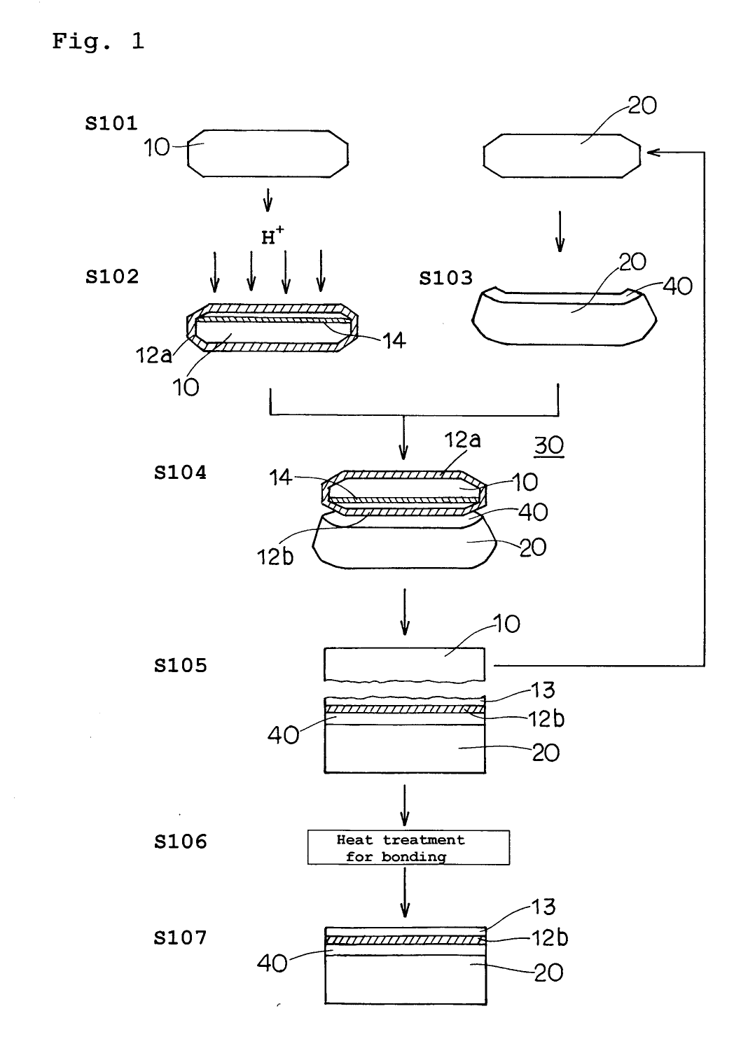

Firstly, a monocrystal ingot of silicon of p-type that has been doped with a predetermined quantity of boron is pulled up in the Cz method, as shown in step S101 of FIG. 1. The rate of pulling up is 1.0 mm/min. After that, the monocrystal ingot of silicon undergoes a series of processing comprising block cutting, slicing, beveling and mirror polishing. Those steps of processing produce a wafer to be prepared as an active layer wafer 10 and a wafer to be prepared as a supporting wafer 20, each of which wafers is of p-type and mirror-polished having a thickness of 725 μm, a diameter of 200 mm, a face orientation of (100) face, a specific resistance of 10 Ωcm.

Following that step, the active layer wafer 10 is introduced into a thermal oxidation device, where the thermal oxidation is applied to the active layer wafer 10 in an oxygen gas atmosphere, as shown in step S102 of FIG. 1. This forms a silicon oxide film 12a having the thickness of about 0.15 μm entirely across the exposed surface of the active layer wafer 10. The condition of thermal treatment may be defined by the thermal treatment at 1000° C. for eight hours.

Subsequently, an intermediate current ion implanting device is used to perform the ion-implantation of the hydrogen with an acceleration voltage of 50 keV into the active layer wafer 10 at a predetermined depth measured from the mirror finished surface thereof. Thus the hydrogen ion implanted area 14 is formed in the active layer wafer 10. The dose used in this step is 5×10¹⁶ atoms/cm².

Subsequently, the supporting wafer 20 is introduced into a CVD device of single wafer processing type, though not shown, where an epitaxial layer 40 of P⁺ type having the boron concentration in a range of 5×10¹⁸ to 8×10¹⁸ atoms/cm³ grows over the mirror finished surface of the supporting wafer 20, as shown in step S103 of FIG. 1.

Specifically, the supporting wafer is loaded on a susceptor arranged in a reaction furnace of the epitaxial growth unit. After that, the SiHCL₃ gas (0.1 volume percent diluted by Hₛ gas) is mixed with the B₂H₆ gas (partial pressure in a range of 2˜4×10⁻⁵), and the resultant mixture is supplied to the reaction furnace at a rate of 80 litter/min to cause the epitaxial layer 40 to grow on top of the supporting wafer 20.

The temperature used for the epitaxial growth is 1100° C. The thickness of the epitaxial layer 40 can be adjusted by changing the epitaxial growth time in dependence on a curvature of the surface (the fitting surface) of the active layer wafer 10. Thus,the epitaxial layer 40 having a specific resistance in a range of 10 to 15 mΩcm and including the surface (the fitting surface) in consistency with a convexity or concavity of the surface of the active layer wafer 10 can be formed on the surface of the supporting wafer 20. The growth of the epitaxial layer 40 causes the warp to be generated in the supporting wafer 20, so that a center region of the wafer may protrude toward the back surface. Owing to this, each of the fitting surfaces of the active layer wafer 10 and the supporting wafer 20 is formed to include a part of the spherical surface of the same curvature. Thus, the active layer wafer 10 and the supporting wafer 20 can be fitted to each other.

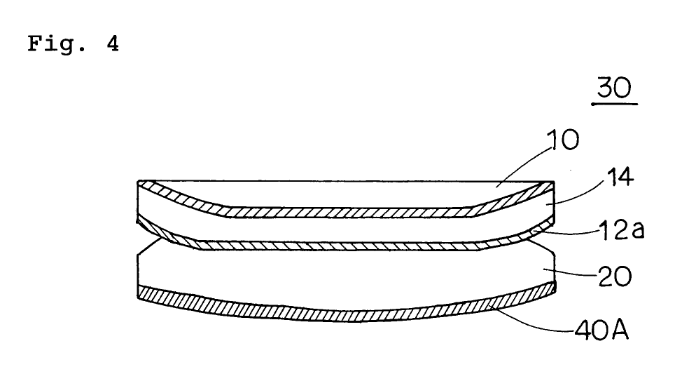

It is to be noted that if employing the boron concentration of 1×10¹⁹ atoms/cm³ in the supporting wafer 20 and the boron concentration of 1×10¹⁵ atoms/cm³ in the epitaxial layer 40A, which is lower than that in the supporting wafer 20, then the warp in the supporting wafer 20 defines a contour of the outer peripheral portion of the wafer that protrudes toward the back surface of the wafer. In this case, the back surface of the supporting wafer 20 is to be used as the bonding surface to produce a bonded wafer (see FIG. 4). Alternatively, the epitaxial layer 40 may be grown not in the supporting wafer 20 but on top of the surface of the active layer wafer. Doing this can reduce a crystal defect, such as COP, in the active layer 13, as well.

Subsequently, the active layer wafer 10 and the supporting wafer 20 are bonded together by using the surface of the silicon oxide film 12a and the surface of the epitaxial layer 40 as the bonding surfaces (the superposed surfaces) with a known jig in a vacuum unit, for example, thus to produce the bonded wafer 30, as shown in step S104 of FIG. 1. As a result of this step, the silicon oxide film 12a at the junction between the active layer wafer 10 and the supporting wafer 20 defines a buried silicon oxide film (insulating film) 12b.

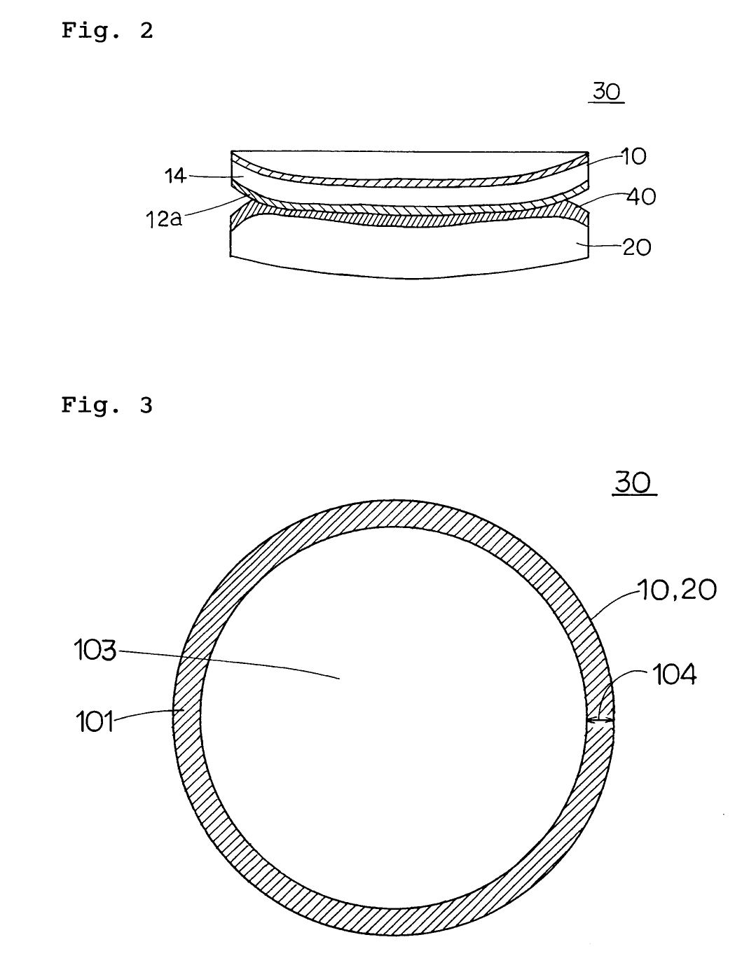

In the bonding, the bonding surfaces of the both wafers 10, 20 define the fitting surfaces that can be fitted to each other. This allows the bonding surfaces to be superposed not only in the central portion of the bonded wafer 30 but also in the outer peripheral portion of the wafer 30 (see FIGS. 2 and 3). Consequently, a width 104 of the area 101 to be left as not-bonded in the outer peripheral portion of the bonded wafer 30 can be reduced to be 2 mm or narrower in comparison to the width of 2 to 3 mm in the prior art and thereby the generation of the void can be suppressed. Therefore, the fixed quality area 103 within the bonded wafer 30, which is usable for the devices to be formed, can be expanded in the order of 1% to 3% as compared with the conventional one. Consequently, the yield of the bonded SOI wafer can be improved and the problem of chipping, peel-off of the wafer and the like in the subsequent steps of wafer processing can be reduced, as well. It is to be noted that the width 104 of the area 101 left as not-bonded refers to the length of the area 101 left as not-bonded in the radial direction of the bonded wafer 30.

Then, the bonded wafer 30 is introduced into a thermal treatment device for cleavage, though not shown, and heat treated in an atmosphere of nitrogen gas at the furnace temperature of 500° C., as shown in step S105 of FIG. 1. The duration of heat treatment is 30 minutes. As a result of this thermal treatment, a part of the active layer wafer 10 is cleaved and separated from the bonded wafer 30 at the site of the hydrogen ion implanted area 14 while leaving the active layer 13 on the bonding interface of the supporting wafer 20. It is also possible to reuse the part of the active layer wafer 10, which has been cleaved off from the bonded wafer 30, as the silicon wafer serving as the supporting wafer 20 for the subsequent manufacturing process.

After the cleavage, the heat treatment for bonding is applied to the bonded wafer 30 in a nitrogen gas atmosphere at 1150° C. for two hours, as shown in step S106 of FIG. 1. This treatment can enhance the bonding strength between the active layer wafer 10 and the supporting wafer 20.

Subsequently, the polishing is applied to the surface of the active layer 13 by a polishing device, as shown in step S107 of FIG. 1. Thus, the bonded SOI wafer (the bonded wafer) having the active layer 13 of about 0.2μm thick has been produced by taking advantage of the smart cut method.

A report on a result obtained from a comparison and examination with respect to the bonded SOI wafers produced in accordance with the present invention method and the prior art method, respectively, will be herein presented specifically on a relationship among the film thickness of the epitaxial layer grown on the surface of the supporting wafer, the warp in the supporting wafer, the number of void generation (as averaged over three pieces of wafers) in an area defined by 20 mm in the radial direction of the wafer from the outermost peripheral edge of the bonded wafer, and the width of the area left as not-bonded (as averaged over three pieces of wafers) in the bonded SOI wafer.

As for the test condition used herein, the same as that in the first embodiment was employed with an exception that no epitaxial layer growth was applied to the supporting wafer in the comparative example 1. The layer thickness of the epitaxial layer was measured by using an SIMS (Secondary Ion Mass Spectroscope). The warp of the supporting wafer was measured by an electrostatic capacity displacement gauge. Visual observation was employed in the examination for the number of void generation. In addition, the measurement by an optical microscope was employed after the cleavage for the purpose of measuring the width of the area left as not-bonded. Table 1 shows the result therefrom. It is to be noted that in Table 1, the number of void generation and the width of the area left as not-bonded indicate values averaged over three measured wafers.

TABLE 1

| | | | Number of void generation | |
|---|---|---|---|---|
| | | Warp of supporting wafer | in an area defined by 20 | |
| | P⁺ Epitaxial layer | (reference taken as before | mm from the wafer outer | Width of area left |
| | thickness (μm) | epi-film deposition) (μm) | periphery (number) | as not-bonded (mm) |
| Comparative example 1 | 0 | 0 | 2.3 | 2.2 |
| Test example 1 | 0.5 | 47 | 0.9 | 1.8 |
| Test example 2 | 1.0 | 92 | 0.6 | 1.6 |
| Test example 3 | 2.0 | 182 | 0.2 | 1.5 |

As clearly seen in Table 1, both of the number of void generation and the width of the area left as not-bonded have been improved favorably in any one of the test examples 1 to 3, in which the epitaxial layer growth was performed on the supporting wafer, as compared to the comparative example 1, in which no epitaxial layer growth was applied onto the supporting wafer.

Second Embodiment

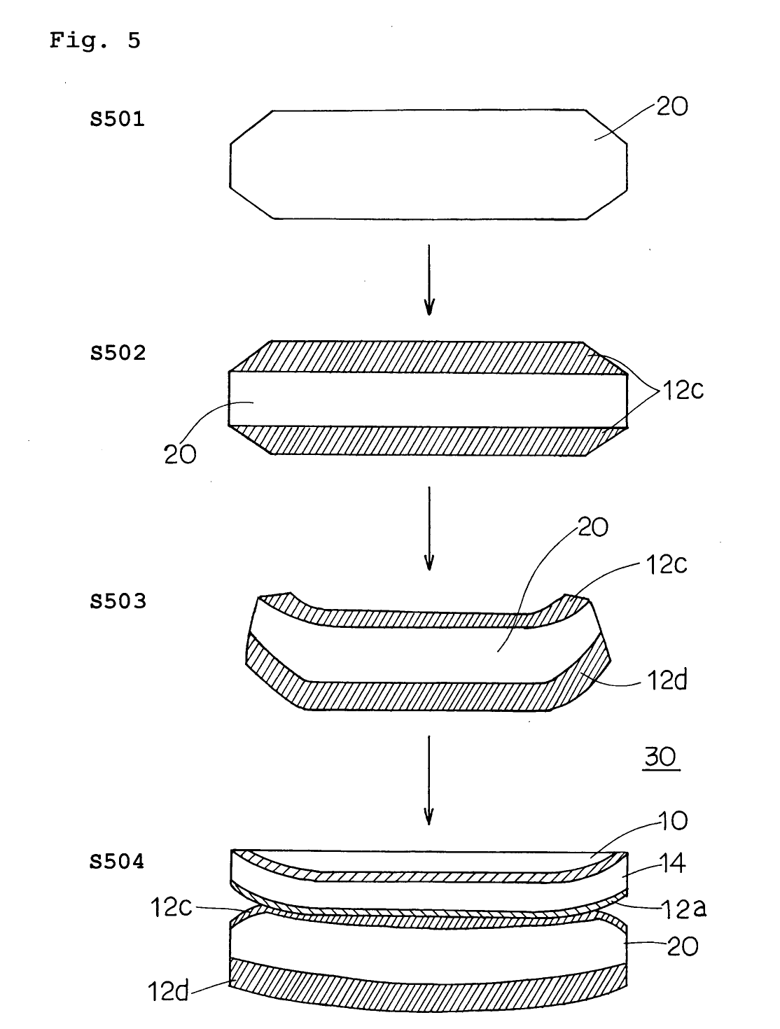

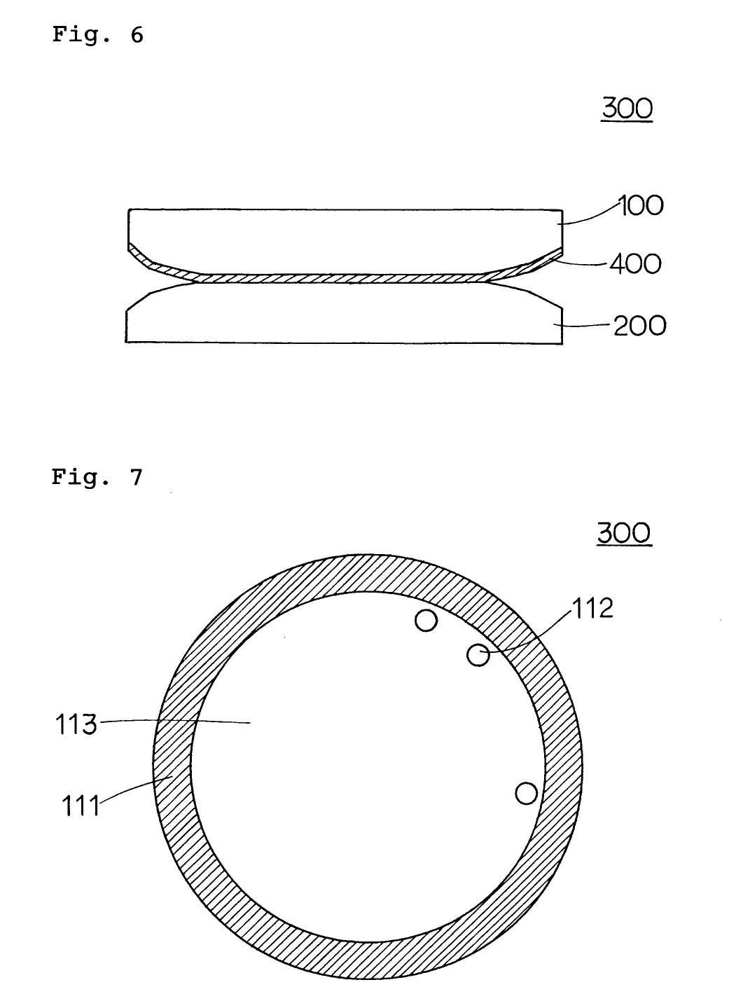

A manufacturing method of a bonded wafer according to a second embodiment of the present invention will now be described with reference to a process chart of FIG. 5.

The second embodiment represents an example of manufacturing method, in which firstly a hetero structure is provided by forming a silicon oxide film 12c, 12d entirely over an exposed surface of the supporting wafer 20, and secondly a warp is generated in the supporting wafer by differentiating the film thickness of the silicon oxide film in the top surface side (the silicon oxide film 12c) from that in the back surface side (the silicon oxide film 12d), as shown in FIG. 5.

Specifically, at first before the bonding step, the supporting wafer 20 is introduced into a thermal treatment device, where it is subjected to a heat treatment for oxidation in an oxygen gas atmosphere, as shown in step S501 and step S502 of FIG. 5. This produces the silicon oxide film 12c having the thickness of 0.3 μm entirely over the exposed surface of the supporting wafer 20. The condition for the heat treatment is defined by a wet oxidation (a pyrogenic oxidation) at 950° C. for one hour.

After that step, the supporting wafer 20 is loaded on a single side cleaning device of single wafer processing type, where the silicon oxide film 12c in the wafer top surface (the bonding surface) is exclusively brought into contact with an HF solution of one weight percent for a predetermined time so as to provide the etching in the top surface side of the wafer and thereby to form the thinner silicon oxide film 12c. As a result, the warp is generated in the supporting wafer 20, as shown in step S503 of FIG. 5. As the volume of etching increases, the film thickness difference of the silicon oxide film 12c in the top surface side from the silicon oxide film 12d in the back surface side of the wafer increases. Consequently, the degree of warp of the supporting wafer 20 is increased, as well. As shown in step S504 of FIG. 5, the degree of warp of the supporting wafer 20 is controlled in dependence on the curvature of the top surface (the fitting surface) of the active layer wafer 10 to be bonded together.

As discussed above, in the present invention, since the thickness of the silicon oxide film 12c, 12d has been differentiated between the top and the back surfaces of the supporting wafer 20 so as to induce the warp in the supporting wafer 20, therefore such an SOI bonded wafer that has achieved the effects from the first embodiment can be manufactured inexpensively.

The configuration, operation and effect of the second embodiment are identical to those in the first embodiment, and so the description thereof is herein omitted.

A report on a result obtained from a comparison and examination with respect to the bonded SOI wafers produced in accordance with the present invention method and the prior art method, respectively, will be herein presented specifically on a relationship among the film thickness difference of the silicon oxide film between the top and the back surfaces of the supporting wafer, the warp in the supporting wafer, the number of void generation (as averaged over three pieces of wafers) in an area defined by 20 mm in the radial direction of the wafer from the outermost peripheral edge of the bonded wafer, and the width of the area left as not-bonded (as averaged over three pieces of wafers) in the bonded SOI wafer.

As for the test condition used herein, the same as that in the first embodiment was employed with an exception that no film thickness difference of the silicon oxide film between the top and the back surfaces of the supporting wafer is applied to the comparative example 2. The film thickness difference of the silicon oxide film between the top and the back surfaces of the supporting wafer was measured by using an ellipso-meter. The warp of the supporting wafer was measured by an electrostatic capacity displacement gauge. An appearance observation with eyes was employed for determining the number of void generation. In addition, the measurement by using an optical microscope was employed for measuring the width of the area left as not-bonded. Table 2 shows the result therefrom. It is to be noted that in Table 2, the number of void generation and the width of the area left as not-bonded indicate values averaged over three measured wafers.

TABLE 2

| | Oxide film thickness | | Number of void generation | |
|---|---|---|---|---|
| | difference between the | Warp of supporting wafer | in an area defined by 20 | |
| | top and the back surfaces | (reference taken as before | mm from the wafer outer | Width of area left |
| | of a supporting wafer (μm) | oxide film deposition) (μm) | periphery (number) | as not-bonded (mm) |
| Comparative example 2 | 0 | 0 | 2.3 | 2.2 |
| Test example 4 | 0.05 | 1.6 | 2.1 | 2.1 |
| Test example 5 | 0.1 | 3.3 | 1.8 | 1.9 |
| Test example 6 | 0.2 | 6.2 | 1.1 | 1.9 |

As clearly seen in Table 2, both of the number of void generation and the width of the area left as not -bonded have been improved favorably in any one of the test examples 4 to 6, in which the film thickness difference of the silicon oxide film is provided between the top and the back surfaces of the supporting wafer, as compared to the comparative example 2, in which the film thickness of the silicon oxide-film is identical between the top and the back surfaces of the wafer.

1. A manufacturing method of a bonded wafer, in which said bonded wafer is manufactured by bonding a wafer for active layer wafer with a supporting wafer, wherein
said active layer wafer and said supporting wafer, which are to be bonded together, have fitting surfaces, respectively, for fitting to each other, each of said fitting surfaces comprising a part of a spherical surface having the same curvature.

2. A manufacturing method of a bonded wafer in accordance with claim 1, in which at least either one of said fitting surface of said active layer wafer and said fitting surface of said supporting wafer includes a hetero structure along a thickness-wise direction.

3. A manufacturing method of a bonded wafer in accordance with claim 2, in which said hetero structure is provided along the thickness-wise direction in the epitaxial growth method.

4. A manufacturing method of a bonded wafer in accordance with claim 1, in which at least either one of said fitting surface of said active layer wafer and said fitting surface of said supporting wafer includes an insulating film along a thickness-wise direction.

5. A manufacturing method of a bonded wafer in accordance with claim 2, in which said hetero structure is disposed in a top and a back surfaces, respectively, of said active layer wafer or said supporting wafer, and said hetero structure in said top and the back surfaces are different in thickness from each other.

6. A manufacture method of a bonded wafer in accordance with claim 1, comprising the steps of
ion-implanting of hydrogen gas or noble gas into said active layer wafer to form an ion-implanted layer in said active layer wafer;
subsequently bonding said active layer wafer with said supporting wafer to form said bonded wafer; and then
heat treating said bonded wafer by holding it at a predetermined temperature so as to induce a cleavage and separation at the site of ion-implanted layer as an interface.

7. A bonded wafer manufactured by bonding an active layer wafer with a supporting wafer, in which
said active layer wafer and said supporting wafer, which are to be bonded together, have fitting surfaces, respectively, for fitting to each other, each of said fitting surfaces comprising a part of a spherical surface having the same curvature.

8. A manufacturing method of a bonded wafer in accordance with claim 3, in which said hetero structure is disposed in a top surface and a back surface, respectively, of said active layer wafer or said supporting wafer, and said hetero structure in said top and back surfaces are different in thickness from each other.

9. A manufacturing method of a bonded wafer in accordance with claim 4, in which said insulating film is disposed in a top surface and a back surface, respectively, of said active layer wafer or said supporting wafer, and said insulating film in said top and the back surfaces are different in thickness from each other.

10. A manufacture method of a bonded wafer in accordance with claim 2, comprising the steps of:
ion-implanting of hydrogen gas or noble gas into said active layer wafer to form an ion-implanted layer in said active layer wafer;
subsequently bonding said active layer wafer with said supporting wafer to form said bonded wafer; and then
heat treating said bonded wafer by holding it at a predetermined temperature so as to induce a cleavage and separation at the site of ion-implanted layer as an interface.

11. A manufacture method of a bonded wafer in accordance with claim 3, comprising the steps of:
ion-implanting of hydrogen gas or noble gas into said active layer wafer to form an ion-implanted layer in said active layer wafer;
subsequently bonding said active layer wafer with said supporting wafer to form said bonded wafer; and then
heat treating said bonded wafer by holding it at a predetermined temperature so as to induce a cleavage and separation at the site of ion-implanted layer as an interface.

12. A manufacture method of a bonded wafer in accordance with claim 4, comprising the steps of:
ion-implanting of hydrogen gas or noble gas into said active layer wafer to form an ion-implanted layer in said active layer wafer;
subsequently bonding said active layer wafer with said supporting wafer to form said bonded wafer; and then
heat treating said bonded wafer by holding it at a predetermined temperature so as to induce a cleavage and separation at the site of ion-implanted layer as an interface.

13. A manufacture method of a bonded wafer in accordance with claim 5, comprising the steps of:
ion-implanting of hydrogen gas or noble gas into said active layer wafer to form an ion-implanted layer in said active layer wafer;
subsequently bonding said active layer wafer with said supporting wafer to form said bonded wafer; and then
heat treating said bonded wafer by holding it at a predetermined temperature so as to induce a cleavage and separation at the site of ion-implanted layer as an interface.
